(19) United States
(12) Patent Application Publication
(10) Pub. No.: US 2004/0164346 A1
(43) Pub. Date: Aug. 26, 2004

(54) Power switching transistor with low drain to gate capacitance

(75) Inventor: Prasad Venkatraman, Gilbert, AZ (US)

Correspondence Address: James J. Stipanuk, Semiconductor Components Industries, L.L.C, Patent Administration Dept - MD/A700, P.O. Box 62890, Phoenix, AZ, 85082-2890, US

(73) Assignee: Semiconductor Components Industries, LLC.

(21) Appl. No.: 10/369,236

(22) Filed: Feb. 20, 2003

(51) Int. Cl. H01L 29/76

(52) U.S. Cl. 257/328

(57) ABSTRACT

A transistor (10) is formed on a semiconductor substrate (12) with a first surface (19) for forming a channel (40) to control a channel current (I_{DS}) A gate electrode (25) is formed over first and second sections of the channel, and a drain region (13, 14, 21) extending from the top surface to a bottom surface (18) of the substrate is formed with a recessed region (30) between the first and second sections of the channel for disposing a dielectric film (20).

### BACKGROUND OF THE INVENTION

The present invention relates in general to semiconductor devices and, more particularly, to vertical MOS power transistors.

Switching regulators achieve a high efficiency by using a transistor to switch current through an inductor or transformer to generate a regulated output voltage. One type of switching transistor used in switching regulators is a power double diffused metal-oxide-semiconductor (DMOS) transistor. A DMOS transistor often is formed as a vertical device in which current flows laterally through a plurality of electrically parallel channels formed along the top surface of a semiconductor die to a common drain, and then vertically through the drain to a drain electrode formed at the bottom surface of the die.

Existing DMOS transistors have the drawback of a high drain to gate capacitance, which slows down the switching time and reduces the efficiency of the transistor and/or system. As a result, the switching regulators have a low efficiency and the transistor has a high heat dissipation and reduced reliability. In order to achieve a small die size and low cost, the gate electrode is formed over a thin dielectric layer and routed over portions of the common drain that lie at the top surface. The overlap of the gate electrode and common drain generates a substantial portion of the overall drain to gate capacitance and results in a reduction in the switching speed and frequency response of the switching power transistor.

Hence, there is a need for a power transistor that has a low drain to gate capacitance in order to switch at a higher rate to reduce power dissipation and increase reliability.

### BRIEF DESCRIPTION OF THE DRAWINGS

FIG. 1 is a cross-sectional view of a vertical power transistor;

FIG. 2 is a cross-sectional view of the transistor in a first alternate embodiment; and

FIG. 3 is a cross-sectional view of the transistor in a second alternate embodiment.

### DETAILED DESCRIPTION OF THE DRAWINGS

In the figures, elements having the same reference number have similar functionality.

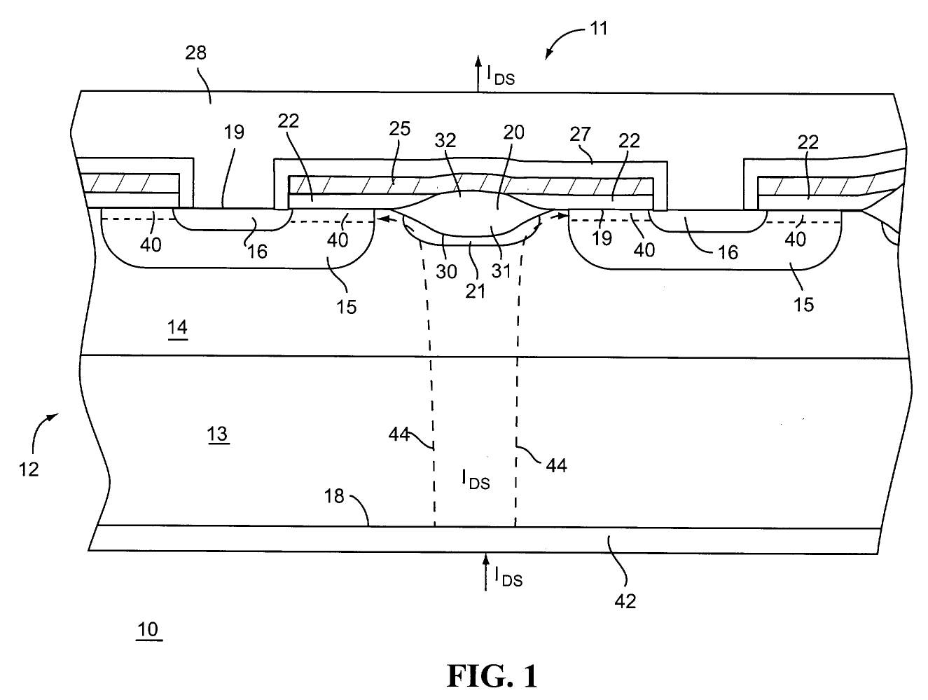

FIG. 1 is a cross-sectional view of a vertical power transistor 10 formed on a semiconductor substrate 12 and configured as a double-diffused metal-oxide-semiconductor (DMOS) transistor. A plurality of unit cells 11 typically are connected on a horizontal top surface 19 of substrate 12 to form an array of rows, columns, cells or similar patterns. Alternatively, transistor 10 may be formed as a single, continuous, serpentine or branched layout.

Each unit cell 11 includes two channel regions or sections of a channel 40 running along top surface 19 and formed by inverting portions of a well region 15. Discrete sections of channel 40 are parallel-connected as described below and also coupled to other sections of channel 40 out of the view plane of FIG. 1 in order to provide a high current capability. In one embodiment, substrate 12 is formed with n-type monocrystalline silicon, and transistor 10 is an n-channel device specified to operate at a drain to source voltage of at least thirty volts and a drain current I_{DS} of at least 0.5 amperes. In one embodiment, transistor 10 is formed as a planar device with its drain electrode at the top surface to form a lateral DMOS device.

A sublayer 13 is formed at a bottom surface 18 of substrate 12, and is heavily doped so that transistor 10 operates with a low on resistance. In one embodiment, sublayer 13 has an n-type conductivity and a doping concentration of about 10¹⁹ atoms/centimeter³. In an alternate embodiment, sublayer 13 has a p-type conductivity for configuring transistor 10 as an insulated gate bipolar transistor. In other embodiments, the conductivity types of the doped regions described herein may be reversed to form, for example, an analogous p-channel device.

An epitaxial layer 14 is formed over sublayer 13 with a doping concentration selected to provide a desired breakdown voltage. In one embodiment, epitaxial layer 14 is lightly to moderately doped with a n-type conductivity, a thickness in a range between about two micrometers and about fifty micrometers and a doping concentration in a range between about 10¹⁴ and about 1*10¹⁷ atoms/centimeter³. In one embodiment, epitaxial layer 14 has an n-type conductivity and a thickness of about three micrometers and a doping concentration of about 2*10¹⁶ atoms/centimeter³. Epitaxial layer 14 and sublayer 13 function as a common drain of transistor 10.

Well region 15 is formed at top surface 19 and into epitaxial layer 14 with a doping profile selected to provide a predetermined conduction threshold of transistor 10. In one embodiment, well region 15 has a p-type conductivity, a depth of about one micrometer, and a surface doping concentration of about 5*10¹⁷ atoms/centimeter³. Well region 15 is electrically interconnected at surface 19 with other well regions 15 out of the view plane of FIG. 1.

A source region 16 is formed at top surface 19 within well region 15 for electrically coupling to two sections of channel 40 formed in each well region 15. Source region 16 is heavily doped to provide a low on resistance. In one embodiment, source regions 16 are formed to have an n-type conductivity, a depth of about 0.2 micrometers, and a doping concentration of about 10²⁰ atoms/centimeter³. Source region 16 is electrically connected to well regions 15 and other source regions 16 out of the view plane of FIG. 1.

A gate dielectric 22 is formed over surface 19 to support an electric field that inverts underlying portions of well regions 15 to form channels 40. Gate dielectric 22 typically has a thickness in a range between about seventy-five angstroms and about one thousand angstroms. In one embodiment, gate dielectric 22 is formed as a thermally grown silicon dioxide having a thickness of about four hundred angstroms.

A gate electrode 25 is formed with a conductive material over gate dielectric 22 to receive a control signal that modulates the conduction of channel 40. In one embodiment, gate electrode 25 is formed with polycrystalline silicon heavily doped to provide a low resistance. In one embodiment, gate electrode 25 is formed with an n-type conductivity and is deposited to a thickness of about 0.65 micrometers. Discrete portions of gate electrode 25 are connected together out of the view plane.

A dielectric region 20 is formed over surface 19 between adjacent portions of gate dielectric 22 as shown. Dielectric region 20 is made thicker than gate dielectric 22 in order to increase the separation between epitaxial layer 14 and gate electrode 25, thereby reducing the corresponding component of the drain to gate capacitance of transistor 10. In one embodiment, dielectric region 20 is formed using a standard locally oxidized semiconductor (LOCOS) or similar process. In one such process, an exposed portion of epitaxial layer 14 is thermally oxidized through an opening in a hard mask (not shown) made of, for example, silicon nitride. A drain enhancement region 21 is formed by implanting n-type dopants into the opening to increase the local conductivity of epitaxial region 14, further reducing the on resistance of transistor 10 and disabling a parasitic junction field-effect transistor of transistor 10. Since drain enhancement region 21 and dielectric region 20 are defined with the same hard mask, drain enhancement region 21 is effectively self-aligned to dielectric region 20, which allows the spacing between adjacent well regions 15 to be reduced while maintaining a separation between well region 15 and drain enhancement region 21. Hence, there is little or no increase in the drain to gate capacitance yet the resulting structure retains the above mentioned benefits with a smaller die area and a lower cost.

A thermal process then converts the exposed semiconductor material to a semiconductor-based dielectric material such as silicon dioxide. During the thermal process, oxygen, for example, diffuses under the edges of the hard mask to oxidize semiconductor material and form a tapered “bird's beak” feature around the perimeter of dielectric region 20. The semiconductor-based dielectric material has a volume greater than that of the consumed semiconductor material, so dielectric region 20 is formed with a lower portion 31 within a recessed region 30 below the plane of surface 19 and an upper portion 32 extending above surface 19. Dielectric region 20 typically is formed with a thickness ranging between about two thousand angstroms and about ten thousand angstroms, depending on the specified breakdown voltage. In one embodiment, dielectric region 20 is formed with an overall thickness of about six thousand angstroms, with lower portion 31 having a thickness of about four thousand angstroms and upper portion 32 having a thickness of about two thousand angstroms.

The combination of a tapered topography and an at least partially recessed film provides a relatively planar surface that facilitates good step coverage so that overlying films such as gate electrode 25 are highly conformal, with little or no thinning and a consequent high reliability. Hence, dielectric region 20 avoids steep vertical steps while providing a thicker film that results in a low drain to gate capacitance.

A dielectric layer 27 is formed over gate electrode 25 and other regions for electrical isolation from subsequent metallization interconnect layers. In one embodiment, dielectric layer 27 is formed with silicon dioxide deposited to a thickness of about 0.5 micrometers.

A metal interconnect film is deposited over surfaces of transistor 10 and patterned to form a source electrode 28 as shown. In one embodiment, source electrode 28 has a thickness of about three micrometers. A region of the metal film outside of the view plane is used to form a gate terminal for interconnecting gate electrodes 25.

A metal layer is formed on bottom surface 18 to form a drain electrode 42 for externally routing drain current I_{DS} flowing through channels 40. In one embodiment, drain electrode 42 is about three micrometers thick.

In operation, an appropriate control voltage is applied to gate electrode 25 to enable channels 40. The control voltage electrically couples source electrode 28 to drain electrode 42 and allows a channel current I_{DS} to flow from drain electrode 42 through sublayer 13, epitaxial layer 14, drain enhancement region 21, channel 40 and source region 16 to source electrode 28. The current flows generally along current lines 44 as shown.

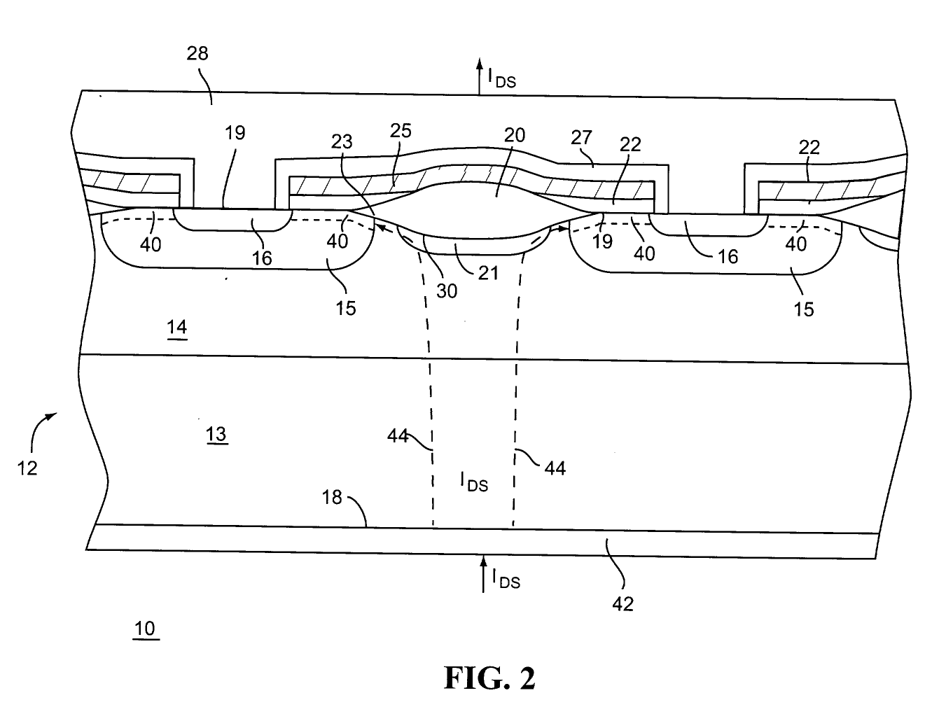

FIG. 2 is a cross-sectional view of transistor 10 in an alternate embodiment. Elements of transistor 10 have structures and operation similar to those described previously, except that dielectric region 20 is extended laterally to overlie an edge 23 of well region 15 and a portion of channel 40. This approach increases the overall vertical separation between gate electrode 25 and epitaxial region 14, which is at all points determined by the thickness of dielectric region 20 rather than by gate dielectric 22. This arrangement achieves a lower drain to source capacitance and higher switching speed than what is provided by other devices.

The conduction threshold voltage of transistor 10 is a function of both the doping concentration of well region 15 and the thickness of gate dielectric 22. The conduction threshold increases as the thickness of gate dielectric 22 increases and the surface doping concentration of well region 15 increases. The conduction threshold voltage decreases as either the thickness of gate dielectric 22 or the doping concentration of well region 15 decreases. In one embodiment, the conduction threshold voltage of transistor 20 is selected to be about 1.5 volts.

Since dielectric region 20 overlaps edge 23, the gate dielectric film is thicker over one portion of channels 40, i.e., due to region 20, than over the remaining portion, i.e., due to gate dielectric 22. The portion of channel 40 underlying dielectric region 20 tends to have a higher threshold because of the greater thickness of dielectric region 20. However, well region 15 has a lower doping concentration at edge 23 than its concentration adjacent to source region 16 due to dopant outdiffusion during fabrication. The lower doping concentration offsets any increase attributable to the greater thickness of dielectric region 20, so a substantially uniform conduction threshold is maintained along the entire length of channels 40. Hence, the overlap of channels 40 by dielectric region 20 provides transistor 10 with a lower drain to gate capacitance, a higher switching speed and/or higher frequency response without degrading its conduction threshold voltage. In one embodiment, channel 40 has a length of about 0.8 micrometers and region 20 overlies channels 40 by about 0.3 micrometers without altering the conduction threshold of transistor 10.

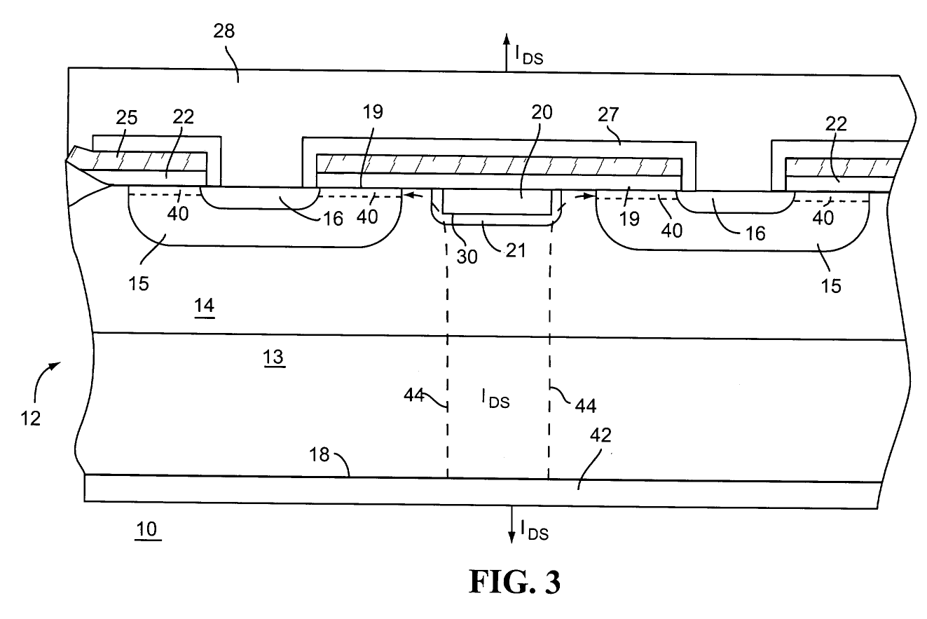

FIG. 3 shows a cross-sectional view of transistor 10 in yet another alternate embodiment in which recessed region 30 is formed with an anisotropic etch process. Dielectric material is disposed on semiconductor substrate 12, followed by an etchback planarization, timed etch, chemical-mechanical polish, or similar process that removes dielectric material from surface 19 while leaving recessed region 30 filled to form dielectric region 20 in a totally recessed embodiment. In this embodiment, the path of gate electrode 25 across dielectric region 20 is substantially planar, thereby providing a low drain to gate capacitance with virtually no film thinning because gate electrode 25 is not routed over any steps.

In summary, the present invention provides a transistor with a reduced drain to gate capacitance and a high switching speed and frequency response. A substrate has a top surface for forming a channel to control a channel current, and a gate electrode is formed over first and second sections of the channel. A drain region extends from the top surface to a bottom surface of the substrate and has a recessed region between the first and second sections of the channel for disposing a dielectric film. The gate electrode is routed over the dielectric film to concurrently control the first and second sections of the channel. The dielectric film increases the spacing between the gate electrode and the drain region in order to reduce the drain to gate capacitance and improve the switching speed.

What is claimed is:

1. A transistor, comprising:
a semiconductor substrate having a top surface for forming a channel to control a channel current;
a gate electrode formed over first and second sections of the channel; and
a drain region extending from the top surface to a bottom surface of the semiconductor substrate, and formed with a recessed region between the first and second portions of the channel for disposing a dielectric film.

2. The transistor of claim 1, further comprising a gate dielectric formed with a first thickness between the gate electrode and the top surface, wherein the dielectric film has a second thickness greater than the first thickness.

3. The transistor of claim 2, wherein the first thickness of the gate dielectric is less than about six hundred angstroms.

4. The transistor of claim 2, wherein the second thickness of the dielectric film is greater than about three thousand angstroms.

5. The transistor of claim 1, wherein the gate electrode comprises a conductive film that extends over the recessed region.

6. The transistor of claim 5, wherein the gate electrode comprises doped polycrystalline silicon.

7. The transistor of claim 1, wherein the dielectric film comprises a silicon dioxide layer formed within the recessed region.

8. The transistor of claim 7, wherein the silicon dioxide layer is thermally grown.

9. The transistor of claim 7, wherein the silicon dioxide layer is deposited.

10. The transistor of claim 1, further comprising a well region formed at the top surface for providing the channel.

11. The transistor of claim 10, wherein the drain region is electrically coupled to a first end of the channel, further comprising:
a source region formed in the well region for electrically coupling to a second end of the channel; and
a drain electrode formed at the bottom surface for electrically coupling through the drain region to the first end of the channel.

12. The transistor of claim 11, further comprising:
a source electrode formed on the top surface for electrically contacting the source region; and
a gate electrode formed over the gate dielectric for controlling a conductivity of the channel.

13. The transistor of claim 1, further comprising a drain enhancement region formed within the drain region under the dielectric film and having the same conductivity type as the drain region.

14. The transistor of claim 13, wherein the drain enhancement region is self-aligned to the dielectric region.

15. The transistor of claim 1, wherein the channel current has a magnitude of at least five hundred milliamperes.

16. A semiconductor device, comprising:
a semiconductor substrate having first and second surfaces;
a well region formed in the semiconductor substrate to provide a channel at the first surface;
a gate electrode formed over first and second portions of the channel;
a drain region extending between the first and second surfaces for electrically coupling to the channel; and
a dielectric region formed in a recessed portion of the drain region between the first and second portions of the channel.

17. The semiconductor device of claim 16, further comprising a gate dielectric formed on the first surface over the channel.

18. The semiconductor device of claim 17, wherein the gate dielectric has a first thickness and the dielectric region has a second thickness greater than the first thickness.

19. The semiconductor device of claim 17, wherein the drain region has an n-type conductivity.
